(19) United States
(12) Patent Application Publication
(10) Pub. No.: US 2005/0247970 A1
(43) Pub. Date: Nov. 10, 2005

(54) Memory device including a dielectric multilayer structure and method of fabricating the same

(75) Inventors: Sanghun Jeon, Yongin-si (KR); Chung-woo Kim, Seongnam-si (KR); Hyunsang Hwang, Gwangju-si (KR)

Correspondence Address: LEE & MORSE, P.C., 1101 WILSON BOULEVARD, SUITE 2000, ARLINGTON, VA, 22209, US

(73) Assignee: Samsung Electronics Co., Ltd.,

(21) Appl. No.: 11/111,991

(22) Filed: Apr. 22, 2005

(30) Foreign Application Priority Data
Apr. 23, 2004 (KR) 10-2004-0028165

(51) Int. Cl. H01L 29/76

(52) U.S. Cl. 257/314

(57) ABSTRACT

In a memory device including a dielectric multilayer structure, and a method of fabricating the same, the memory device includes a semiconductor substrate, a first impurity region and a second impurity region spaced apart from each other in the semiconductor substrate, and a gate structure formed on the semiconductor substrate and contacting the first impurity region and the second impurity region, the gate structure including a tunneling oxide layer on the semiconductor substrate, a charge storage layer on the tunneling oxide layer, an insulating layer on the charge storage layer, the insulating layer including at least two dielectric layers, and a gate electrode layer on the insulating layer.

### BACKGROUND OF THE INVENTION

1. Field of the Invention

The present invention relates to a memory device including a dielectric multilayer structure and a method of fabricating the same. More particularly, the present invention relates to a memory device including a dielectric multilayer structure, the memory device exhibiting characteristics of quick data storing and erasing times and improved data retention time, and a method of fabricating the same.

2. Description of the Related Art

Data storage capacity of a semiconductor memory device is proportional to the number of memory cells per unit area, i.e., the degree of integration. Generally, a semiconductor memory device includes many memory cells, which are connected in circuits. In the case of dynamic random access memory (DRAM), a unit memory cell is generally composed of one transistor and one capacitor. Thus, the volume of the transistor and the capacitor should be reduced in order to increase the integration of the semiconductor memory device.

Early semiconductor memory devices, with a low degree of integration, had sufficient process margins for photolithography and etching. Therefore, reducing the volume of the transistor and capacitor was a rather efficient way of increasing the integration of the semiconductor memory device. However, with technological developments in semiconductor and associated electronics industries, there is an increasing demand for more highly integrated semiconductor memory devices, which cannot be satisfied by existing methods.

The integration of a semiconductor memory device is closely related to a design rule used in the fabrication of the semiconductor memory device. For that reason, a design rule should be more strictly applied in the fabrication, in order to increase the integration of the semiconductor memory device. Thus, since the process margins of photolithography and etching are decreased, it is necessary to apply more precise photolithography and etching in the fabrication of the semiconductor memory device.

If the process margins of photolithography and etching in the fabrication of a semiconductor memory device are low, the production yield is decreased. Therefore, it is necessary to identify new methods of increasing the integration degree of semiconductor memory devices while maintaining production yield.

One new type of semiconductor memory device, which has been introduced in an effort to solve this problem, has a structure which differs from that of a conventional semiconductor memory device in having a data storage medium, such as giant magnetoresistance (GMR) or tunneling magnetoresistance (TMR), formed on a transistor.

A silicon-oxide-nitride-oxide-silicon (SONOS) memory device is one of the recently introduced semiconductor memory devices. FIG. 1A illustrates a sectional view of a typical, conventional SONOS memory device (hereinafter, referred to as “the conventional memory device”). FIG. 1B illustrates a sectional view of another conventional SONOS memory device.

Referring to FIG. 1A, the conventional memory device includes a first impurity region (source) and a second impurity region (drain), which are formed by doping a semiconductor substrate with impurities, and a channel region between the first and the second impurity regions. A gate structure is formed on the semiconductor substrate. The gate structure is made by sequentially forming a tunneling oxide layer, e.g., silicon oxide (SiO₂), a charge storage layer, e.g., silicon nitride (SiN), a blocking oxide layer, e.g., SiO₂, and a gate electrode. The charge storage layer has a trap site with a predetermined density. Thus, if a predetermined voltage is applied to the gate electrode, electrons passing through the tunneling oxide layer are trapped in the trap site of the charge storage layer. The blocking oxide layer prevents the trapped electrons from moving to the gate electrode.

The threshold voltage of the conventional memory device varies according to whether electrons are trapped in the trap sites of the charge storage layer. The conventional memory device stores and reproduces information using this property. However, the conventional SONOS memory device of FIG. 1A has the problems of slow data writing and erasing in the SiO₂/SiN/SiO₂ gate structure thereof, and a short data retention time.

In an effort to solve these problems, another SONOS memory device structure has been introduced in which a nitride charge storage layer is composed of a HfO₂ oxide layer having a high dielectric constant, and a blocking oxide layer is composed of an Al₂O₃ oxide layer having a high dielectric constant, as shown in FIG. 1B. The SONOS memory device structure shown in FIG. 1B solves to some extent the problems of slow data writing and erasing and short data retention, but does not necessarily provide a memory device having improved characteristics.

### SUMMARY OF THE INVENTION

The present invention is therefore directed to a memory device including a dielectric multilayer structure and a method of fabricating the same, which substantially overcome one or more of the problems due to the limitations and disadvantages of the related art.

It is therefore a feature of an embodiment of the present invention to provide a memory device with an improved structure that is capable of enhancing data writing and erasing characteristics.

It is therefore another feature of an embodiment of the present invention to provide a memory device with an improved structure that is capable of improving data retention time.

It is therefore still another feature of an embodiment of the present invention to provide a method of fabricating such a memory device.

At least one of the above and other features and advantages of the present invention may be realized by providing a memory device including a dielectric multilayer structure, the memory device including a semiconductor substrate, a first impurity region and a second impurity region spaced apart from each other in the semiconductor substrate, and a gate structure formed on the semiconductor substrate and contacting the first impurity region and the second impurity region, the gate structure including a tunneling oxide layer on the semiconductor substrate, a charge storage layer on the tunneling oxide layer, an insulating layer on the charge storage layer, the insulating layer including at least two dielectric layers, and a gate electrode layer on the insulating layer.

The tunneling oxide layer may include silicon oxide. A thickness of the tunneling oxide layer may be about 1.5 to about 4 nm.

The charge storage layer may include nitride.

The at least two dielectric layers of the insulating layer may include a first dielectric layer and a second dielectric layer, which are sequentially formed on the charge storage layer, and wherein an energy band gap of the first dielectric layer is greater than an energy band gap of the second dielectric layer.

A thickness of a first dielectric layer of the at least two dielectric layers may be about 2 nm to about 4 nm and a thickness of a second dielectric layer of the at least two dielectric layers may be about 3 nm to about 4 nm.

The at least two dielectric layers of the insulating layer may be composed of a material having a dielectric constant greater than that of silicon oxide.

The at least two dielectric layers may include one of the group including MO, MON, MSiO, and MSiON, wherein M is a metal. The metal may be one selected from the group including aluminum (Al), titanium (Ti), tantalum (Ta), zirconium (Zr), hafnium (Hf), lanthanum (La) and the lanthanide series of elements.

At least one of the above and other features and advantages of the present invention may be realized by providing a method of fabricating a memory device including a dielectric multilayer structure, the method including forming a tunneling oxide layer and a charge storage layer sequentially on a semiconductor substrate, forming an insulating layer including at least two dielectric layers on the charge storage layer, and forming a gate electrode layer on the insulating layer, removing end portions of the gate electrode layer, the insulating layer, the charge storage layer, and the tunneling oxide layer, thereby exposing portions of the semiconductor substrate, and doping the exposed portions of the semiconductor substrate with impurities, thereby forming a first impurity region and a second impurity region.

Forming the insulating layer may include sequentially stacking at least two dielectric layers, which are each composed of a material having a dielectric constant greater than that of silicon oxide.

The at least two dielectric layers may include one of the group including MO, MON, MSiO, and MSiON, wherein M is a metal. The metal may include one selected from the group including aluminum (Al), titanium (Ti), tantalum (Ta), zirconium (Zr), hafnium (Hf), lanthanum (La) and the lanthanide series of elements.

The MON or MSiON may be formed by a method selected from the group including chemical vapor deposition (CVD), atomic layer deposition (ALD), atomic layer chemical vapor deposition (ALCVD), low pressure chemical vapor deposition (LPCVD), plasma enhanced chemical vapor deposition (PECVD), metal oxide chemical vapor deposition (MOCVD), and reactive sputtering.

The MON or MSiON may be formed by initially forming MO or MSiO, and then performing a nitridation process on the MO or MSiO. The nitridation process may include one selected from the group including plasma nitridation in the presence of N₂ or NH₃, rapid temperature annealing (RTA) in the presence of NH₃, furnace treatment in the presence of NH₃, and ion implantation of nitrogen (N) ions. The method may further include performing a reoxidation process selected from the group consisting of rapid temperature annealing (RTA) and furnace treatment, the reoxidation process being performed in the presence of oxygen.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A and 1B illustrate sectional views of conventional SONOS memory devices;

FIG. 2 illustrates a sectional view of a memory device including a dielectric multilayer structure according to an embodiment of the present invention;

FIGS. 3A through 3H illustrate sectional views of stages in a method of fabricating a memory device including a dielectric multilayer structure according to an embodiment of the present invention; and

FIGS. 4A through 4C are graphs illustrating characteristics of a memory device including a dielectric multilayer structure according to an embodiment of the present invention.

### DETAILED DESCRIPTION OF THE INVENTION

Korean Patent Application No. 10-2004-0028165, filed on Apr. 23, 2004, in the Korean Intellectual Property Office, and entitled: “Memory Device Including a Dielectric Multilayer Structure and Method of Fabricating the Same,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

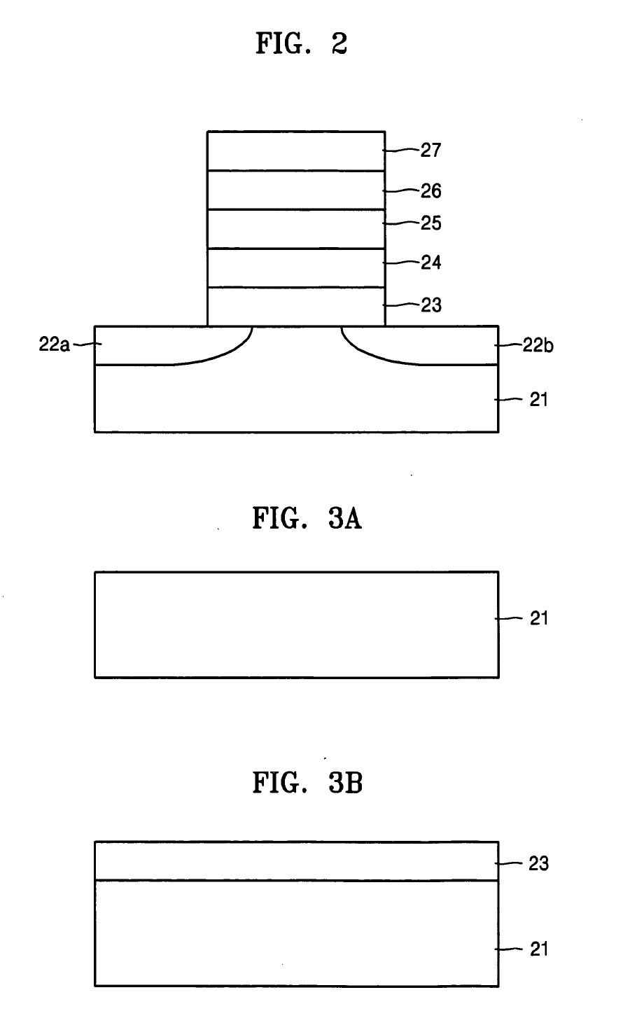

FIG. 2 illustrates a sectional view of a memory device including a dielectric multilayer structure according to an exemplary embodiment of the present invention. Referring to FIG. 2, the memory device includes a semiconductor substrate 21, and a first impurity region 22a and a second impurity region 22b formed in the semiconductor substrate 21. For example, if the semiconductor substrate 21 is a p-type substrate, the first impurity region 22a and the second impurity region 22b are doped with n-type impurities down to a predetermined depth. The first impurity region 22a and the second impurity region 22b are spaced apart from each other by a predetermined distance, and the region between the two impurity regions is a channel region.

A gate structure, which contacts the first impurity region 22a and the second impurity region 22b, is formed on the channel region of the semiconductor substrate 21. In this exemplary embodiment, the gate structure includes a tunneling oxide layer 23, a charge storage layer 24, an insulating layer formed by a first dielectric layer 25 and a second dielectric layer 26, and a gate electrode layer 27, which are sequentially formed.

Both the first impurity region 22a and the second impurity region 22b, which are under the tunneling oxide layer 23, contact the gate structure. The tunneling oxide layer 23 may be composed of SiO₂, or another insulating material. The tunneling oxide layer 23 may preferably be formed to a thickness of about 1.5 to about 4 nm.

The charge storage layer 24 includes trap sites in which electrons are trapped after passing through the tunneling oxide layer 23 when a voltage is applied to the gate electrode layer 27. Therefore, the density of trap sites is preferably high. The charge storage layer 24 is composed of a material having a high dielectric constant, such as a nitride compound or the like. For example, MON or MSiON may be used, wherein “M” represents a metal. The metal may be aluminum (Al), titanium (Ti), tantalum (Ta), zirconium (Zr), hafnium (Hf), lanthanum (La) or one of the lanthanide series of elements, i.e., cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

In this exemplary embodiment of the present invention, the first dielectric layer 25 and the second dielectric layer 26 act as an insulating layer to prevent the electrons trapped in the charge storage layer 24, after passing through the tunneling oxide layer 23, from moving to the gate electrode layer 27. The insulating layer for preventing the movement of electrons to the gate electrode 27, however, may be formed of more than two dielectric layers. As such, the present invention is characterized in that at least two dielectric layers, e.g., the first dielectric layer 25 and the second dielectric layer 26, form the insulating layer. Although FIG. 2 only illustrates the first dielectric layer 25 and the second dielectric layer 26, another dielectric layer, which is composed of a material having a high dielectric constant, may be formed on the second dielectric layer 26. A thickness of the first dielectric layer 25 may be about 2 nm to about 4 nm and a thickness of the second dielectric layer 26 may be about 3 nm to about 4 nm. The first dielectric layer 25 formed on the charge storage layer 24 preferably has a larger energy band gap (E_{g}) than the second dielectric layer 26. Hereinafter, an example of a dielectric multilayer structure including at least two dielectric layers will be explained.

The first dielectric layer 25 and the second dielectric layer 26 are composed of a dielectric material having a high dielectric constant. For example, the dielectric material may be SiO₂, or a high-k dielectric material, i.e., a material having a dielectric constant greater than that of SiO₂. The high-k dielectric material may be MO, MON, MSiO, MSiON, or the like, wherein “M” is a metal. The metal may be aluminum (Al), titanium (Ti), tantalum (Ta), zirconium (Zr), hafnium (Hf), lanthanum (La) or one of the lanthanide series of elements, i.e., cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

The gate electrode layer 27 is formed to apply a voltage while driving the memory device of the present invention. Polysilicon including conductive impurities or a typical metal may be used for the gate electrode 27.

With reference to FIG. 2, the operating principle of the memory device according to an embodiment of the present invention will now be explained. If a voltage is applied on the gate electrode layer 27, and the semiconductor substrate 21 is maintained in a ground state, electrons are injected from the channel region to the trap site of the charge storage layer 24 through the tunneling oxide layer 23, and programmed. Thus, a current signal of the first impurity region 22a and the second impurity region 22b can be read by a data signal.

An explanation of specific driving methods will now be provided. In the case of storing (writing) data, a voltage V_{d} is applied to the second impurity region 22b, and a voltage V_{g} is applied to the gate electrode layer 27. Electrons in the channel region between the first impurity region 22a and the second impurity region 22b pass through the tunneling oxide layer 23 and are trapped in the trap sites of the charge storage layer 24. In the case of reading data, a voltage, V_{d′}(V_{d′}<V_{d}) is applied to the second impurity region 22b, and a voltage, V_{g′}(V_{g′}<V_{g}) is applied to the gate electrode layer 27. An electric current flowing through the channel region between the first impurity region 22a and the second impurity region 22b varies according to whether electrons are trapped in the charge storage layer 24. More specifically, to drive the memory device, if the current flowing through the channel region between the first impurity region 22a and the second impurity region 22b is greater than a standard current, then the state is determined as “1,” and if the current is less than the standard current, then the state is determined as “0.”

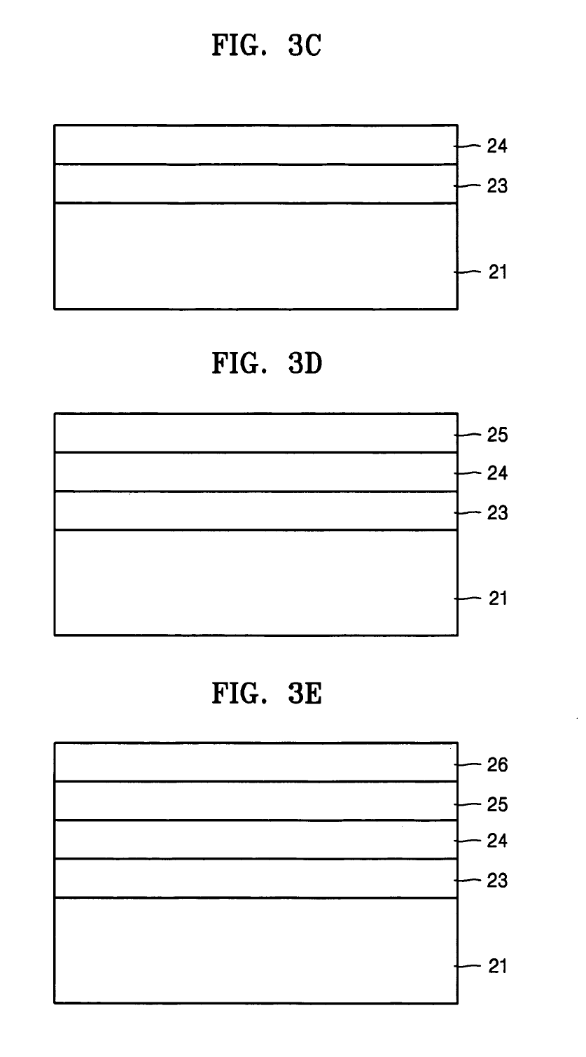

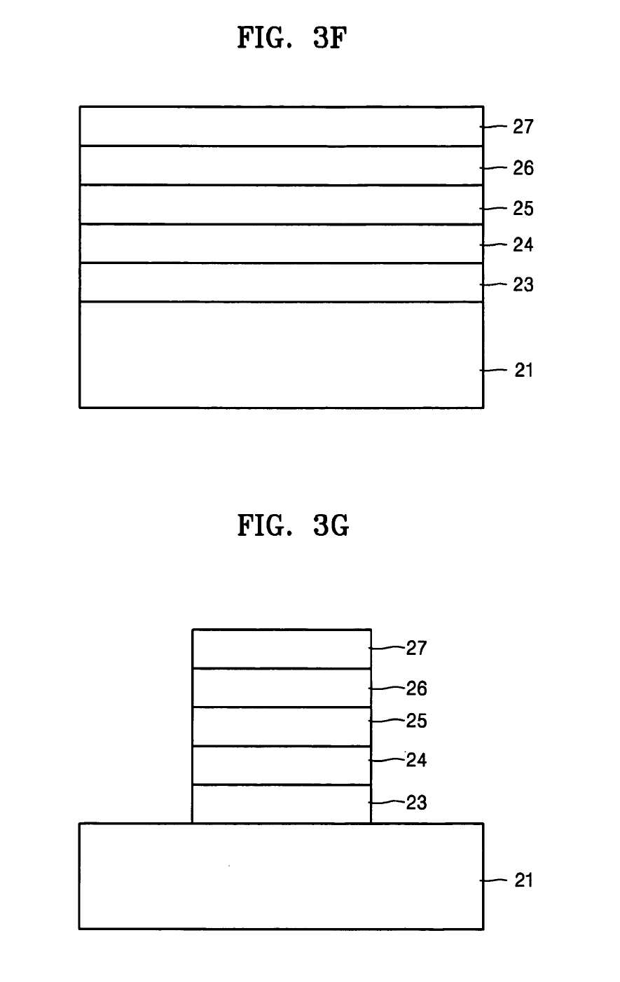

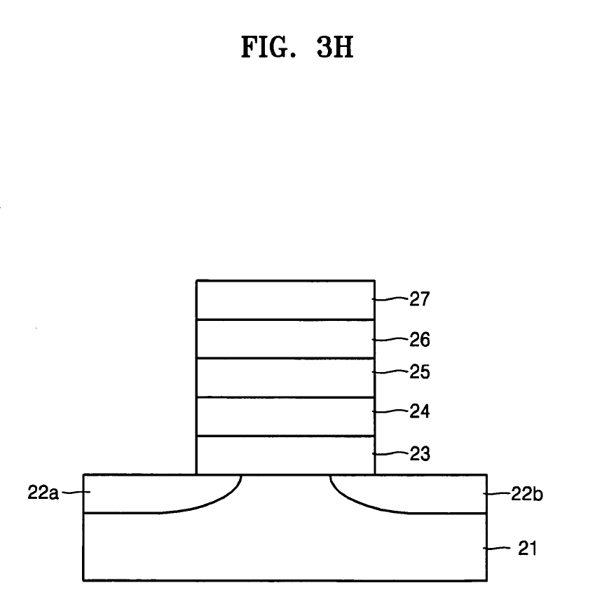

FIGS. 3A through 3H illustrate sectional views of stages in a method of fabricating a memory device including a high-k dielectric multilayer structure according to an embodiment of the present invention. Referring to FIGS. 3A through 3H, a detailed explanation of a method of fabricating a memory device shown in FIG. 2 according to an embodiment of the present invention will now be provided.

Referring to FIG. 3A, the semiconductor substrate 21, which is doped with, e.g., p-type impurities is provided. The kind of semiconductor substrate 21 is not limited, and the semiconductor substrate 21 may employ a silicon substrate, which is normally used in the fabrication of a semiconductor device.

Referring to FIG. 3B, the tunneling oxide layer 23 is formed on the semiconductor substrate 21. The tunneling oxide layer 23 may be composed of SiO₂ with a thickness of about 1.5 to about 4 nm. Then, as shown in FIG. 3C, the charge storage layer 24 is formed on the tunneling oxide layer 23. The charge storage layer 24 may be composed of, e.g., a nitride such as silicon nitride (SiN). In order to increase the trap sites, a porous material may be further deposited on the charge storage layer 24, or the charge storage layer 24 may be doped with impurities.

As shown in FIGS. 3D and 3E, the dielectric multilayer structure of at least two dielectric layers, e.g., the first and second dielectric layers 25 and 26, is formed on the charge storage layer 24. The dielectric material used for the dielectric layers is preferably a high-k dielectric material having a dielectric constant greater than that of SiO₂. Further, the material of the first dielectric layer 25 preferably has a larger energy band gap (Eg) than the material of the second dielectric layer 26. The high-k dielectric material may be MO, MON, MSiO, MSiON, or the like, wherein “M” represents is a metal, and may be aluminum (Al), titanium (Ti), tantalum (Ta), zirconium (Zr), hafnium (Hf), lanthanum (La) or one of the lanthanide series of elements, i.e., cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

In the case of forming MON or MSiON material, chemical vapor deposition (CVD), atomic layer deposition (ALD), atomic layer chemical vapor deposition (ALCVD), low pressure chemical vapor deposition (LPCVD), plasma enhanced chemical vapor deposition (PECVD), metal oxide chemical vapor deposition (MOCVD), or reactive sputtering may be used. In this process, first, MO or MSiO may be deposited on the charge storage layer 24. Next, a nitridation process, e.g., a plasma nitridation in the presence of N₂ or NH₃, a rapid temperature annealing (RTA) in the presence of NH₃, a furnace treatment in the presence of NH₃, or an ion implantation of nitrogen (N) ions, may be performed on the MO or the MSiO, thereby forming MON or MSiON, respectively. Further, if necessary, a reoxidation process, such as RTA or furnace treatment, may be performed in the presence of oxygen. Such a process can be employed both when forming the first dielectric layer 25 and forming the second dielectric layer 26.

Subsequently, as shown in FIG. 3F, the gate electrode layer 27 is formed on the uppermost dielectric layer, which in this exemplary embodiment, is the second dielectric layer 26. The material used for the gate electrode layer 27 may be a typical conductive material. Accordingly, porous silicon or metal may be deposited on the uppermost dielectric layer.

Then, as shown in FIG. 3G, both sides, i.e., end portions, of the gate structure are removed and portions of the semiconductor substrate 21 to either side of the gate structure are exposed. The exposed portions of the semiconductor substrate 21 are then doped with impurities by ion implantation or the like, as shown in FIG. 3H, thereby forming the first impurity region 22a and the second impurity region 22b. Annealing is performed in order to activate the first impurity region 22a and the second impurity region 22b, thereby completing the formation of a memory device including a high-k dielectric multilayer structure according to an embodiment of the present invention, as shown in FIG. 2.

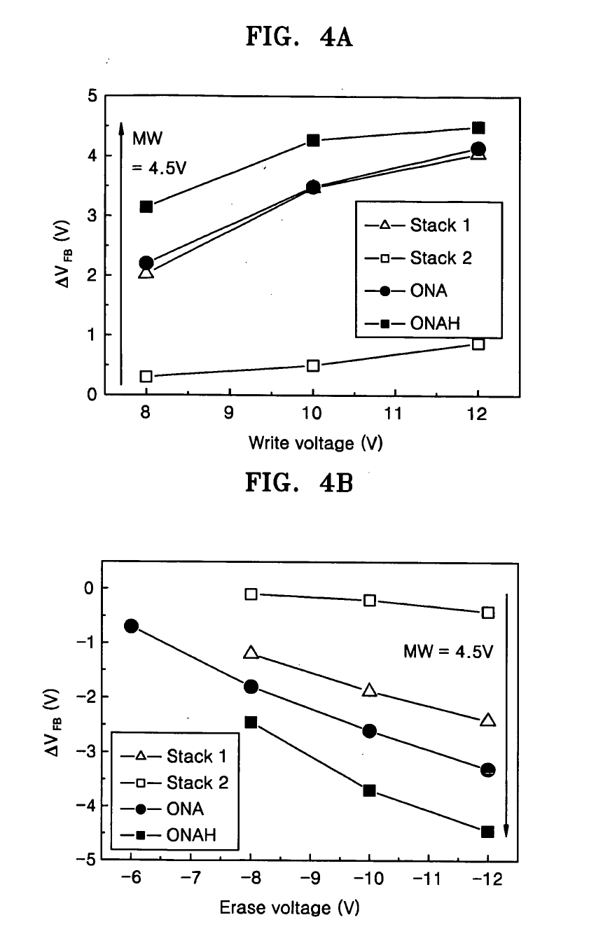

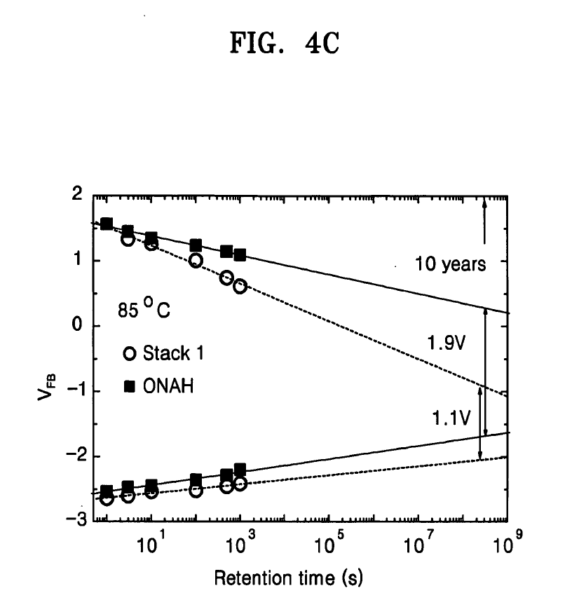

FIGS. 4A through 4C are graphs illustrating characteristics of a memory device including a dielectric multilayer structure according to an embodiment of the present invention.

A comparison of the characteristics of a memory device including a high-k dielectric multilayer structure according to an embodiment of the present invention and a conventional memory device is explained with reference to FIGS. 4A through 4C. Four samples were fabricated and characteristics of each were analyzed in order to compare the memory device according to the embodiment of the present invention to the conventional memory device. The materials of the tunneling oxide layer, the charge storage layer and the insulating layer (dielectric layer or blocking oxide layer) of each of the four samples, and the thicknesses thereof, are shown in Table 1.

TABLE 1

| | tunneling oxide | charge storage | |
|---|---|---|---|
| | layer (thickness | layer (thickness | insulating layer |
| | (nm)) | (nm)) | (thickness (nm)) |
| stack 1 | SiO₂ (1.8) | SiN (6) | SiO₂ (8) |
| (conventional | | | |
| technology) | | | |
| stack 2 | SiO₂ (3.5) | SiN (6) | SiO₂ (5) |
| (conventional | | | |
| technology) | | | |
| ONA | SiO₂ (3.5) | SiN (6) | Al₂O₃ (4-5) |
| (conventional | | | |
| technology) | | | |
| ONAH (present | SiO₂ (3.5) | SiN (6) | Al₂O₃ |
| invention) | | | (2-4)/HfO₂(3-4) |

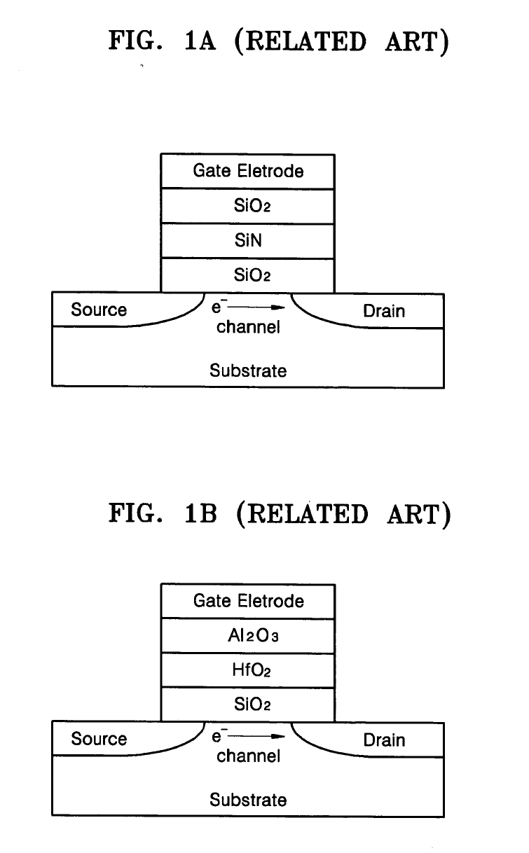

Referring to Table 1, in the sample ONAH according to an embodiment of the present invention, a multilayer structure including Al₂O₃ and HfO₂ having a high dielectric constant as a dielectric layer is formed on the charge storage layer 24 (Eg _{(Al}_{₂}_{O}_{₃})>Eg_{(HfO}_{₂}₎). Stack 1 and stack 2 samples have the same configuration as the conventional memory device shown in FIG. 1A. The ONA sample has the same configuration as the conventional memory device shown in FIG. 1B.

FIG. 4A is a graph illustrating a variation of flat band voltage (ΔV_{FB}) after applying a data write voltage to each of the four samples in Table 1.

Referring to FIG. 4A, in the case of applying a data write voltage of 8 to 12 V, the flat band voltage difference of the stack 2 sample is generally the least, and the flat band voltage difference of the ONAH sample according to an embodiment of the present invention is the greatest. Thus, even when a small voltage is applied, data can be adequately written in the memory device according to the embodiment of the present invention, because of a sufficient flat band voltage and a large change in flat band voltage. As a result, it is determined that the data recording time in the memory device according to the embodiment of the present invention is shorter than in the conventional memory device.

FIG. 4B is a graph illustrating a variation of flat band voltage (ΔV_{FB}) after applying a data erase voltage to each of the four samples in Table 1.

Referring to FIG. 4B, in the case of applying −6 to −12 V of a data erase voltage, the flat band voltage difference (absolute value) of the stack 2 sample is generally the least, and the flat band voltage difference of the ONAH according to an embodiment of the present invention is the greatest. This is consistent with the result of FIG. 4A. In FIG. 4B, even when a small voltage is applied, data can be adequately erased from the memory device according to the embodiment of the present invention because of a sufficient flat band voltage and a large change in flat band voltage. As a result, the data erase time in the memory device according to the embodiment of the present invention is shorter than in the conventional memory device.

FIG. 4C is a graph illustrating data retention time characteristics of the ONAH sample and the stack 1 sample, which exhibited generally good results in FIGS. 4A and 4B.

Referring to FIG. 4C, the difference of flat band voltages (V_{FB}) relative to data retention time (sec.) is initially maintained similar in the two samples. However, at a data retention time of about 10 years, the difference of flat band voltages of the ONAH sample is about 1.9 V while the difference of flat band voltages of the conventional stack 1 sample is about 1.1 V. That is, the ONAH sample showed a flat band voltage difference 70% higher than the flat band voltage difference of the conventional stack 1 sample. From this result, it was determined that the ONAH sample fabricated according to an embodiment of the present invention has superior retention characteristics than the conventional stack 1 sample.

As described above, the present invention provides a memory device capable of being reliably driven in a short time at a low voltage, because the data writing and erasing characteristics are excellent as compared to a conventional SONOS memory device. Further, the present invention can provide a memory device having better data retention characteristics as well as data writing and erasing characteristics than could be realized using conventional technology.

In addition, it can be understood to those skilled in the art that a third dielectric layer having a high dielectric constant may be further provided on the charge storage layer 24, e.g., on the second dielectric layer 26.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A memory device including a dielectric multilayer structure, the memory device including a semiconductor substrate, a first impurity region and a second impurity region spaced apart from each other in the semiconductor substrate, and a gate structure formed on the semiconductor substrate and contacting the first impurity region and the second impurity region, the gate structure comprising:
a tunneling oxide layer on the semiconductor substrate;
a charge storage layer on the tunneling oxide layer;
an insulating layer on the charge storage layer, the insulating layer including at least two dielectric layers; and
a gate electrode layer on the insulating layer.

2. The memory device as claimed in claim 1, wherein the tunneling oxide layer includes silicon oxide.

3. The memory device as claimed in claim 1, wherein a thickness of the tunneling oxide layer is about 1.5 to about 4 nm.

4. The memory device as claimed in claim 1, wherein the charge storage layer includes nitride.

5. The memory device as claimed in claim 1, wherein the at least two dielectric layers of the insulating layer comprise a first dielectric layer and a second dielectric layer, which are sequentially formed on the charge storage layer, and
wherein an energy band gap of the first dielectric layer is greater than an energy band gap of the second dielectric layer.

6. The memory device as claimed in claim 1, wherein a thickness of a first dielectric layer of the at least two dielectric layers is about 2 nm to about 4 nm and a thickness of a second dielectric layer of the at least two dielectric layers is about 3 nm to about 4 nm.

7. The memory device as claimed in claim 1, wherein the at least two dielectric layers of the insulating layer are composed of a material having a dielectric constant greater than that of silicon oxide.

8. The memory device as claimed in claim 1, wherein the at least two dielectric layers comprise one of the group consisting of MO, MON, MSiO, and MSiON, wherein M is a metal.

9. The memory device as claimed in claim 8, wherein the metal is one selected from the group consisting of aluminum (Al), titanium (Ti), tantalum (Ta), zirconium (Zr), hafnium (Hf), lanthanum (La) and the lanthanide series of elements.

10. A method of fabricating a memory device including a dielectric multilayer structure, the method comprising:
forming a tunneling oxide layer and a charge storage layer sequentially on a semiconductor substrate;
forming an insulating layer including at least two dielectric layers on the charge storage layer, and forming a gate electrode layer on the insulating layer;
removing end portions of the gate electrode layer, the insulating layer, the charge storage layer, and the tunneling oxide layer, thereby exposing portions of the semiconductor substrate; and
doping the exposed portions of the semiconductor substrate with impurities, thereby forming a first impurity region and a second impurity region.

11. The method as claimed in claim 10, wherein the tunneling oxide layer is composed of silicon oxide and has a thickness of about 1.5 to about 4 nm.

12. The method as claimed in claim 10, wherein the charge storage layer includes nitride.

13. The memory device as claimed in claim 10, wherein a thickness of a first dielectric layer of the at least two dielectric layers is about 2 nm to about 4 nm and a thickness of a second dielectric layer of the at least two dielectric layers is about 3 nm to about 4 nm.

14. The method as claimed in claim 10, wherein forming the insulating layer comprises sequentially stacking at least two dielectric layers, which are each composed of a material having a dielectric constant greater than that of silicon oxide.

15. The method as claimed in claim 14, wherein the at least two dielectric layers comprise one of the group consisting of MO, MON, MSiO, and MSiON, wherein M is a metal.

16. The method as claimed in claim 15, wherein the metal comprises one selected from the group consisting of aluminum (Al), titanium (Ti), tantalum (Ta), zirconium (Zr), hafnium (Hf), lanthanum (La) and the lanthanide series of elements.

17. The method as claimed in claim 15, wherein the MON or MSiON is formed by a method selected from the group consisting of chemical vapor deposition (CVD), atomic layer deposition (ALD), atomic layer chemical vapor deposition (ALCVD), low pressure chemical vapor deposition (LPCVD), plasma enhanced chemical vapor deposition (PECVD), metal oxide chemical vapor deposition (MOCVD), and reactive sputtering.

18. The method as claimed in claim 15, wherein the MON or MSiON is formed by initially forming MO or MSiO, and then performing a nitridation process on the MO or MSiO.

19. The method as claimed in claim 18, wherein the nitridation process comprises one selected from the group consisting of plasma nitridation in the presence of N₂ or NH₃, rapid temperature annealing (RTA) in the presence of NH₃, furnace treatment in the presence of NH₃, and ion implantation of nitrogen (N) ions.

20. The method as claimed in claim 18, further comprising performing a reoxidation process selected from the group consisting of rapid temperature annealing (RTA) and furnace treatment, the reoxidation process being performed in the presence of oxygen.
